(19) United States
(12) Patent Application Publication
(10) Pub. No.: US 2026/0268033 A1
(43) Pub. Date: Sep. 10, 2026

(54) SCENE RENDERING METHOD AND APPARATUS FOR LARGE-SCALE DIGITAL TWIN MODEL, DEVICE, MEDIUM, AND PRODUCT

(71) Applicant: Wenzhou University, Wenzhou (CN)

(72) Inventors: Liang SHU, Wenzhou (CN); Yong XUAN, Wenzhou (CN); Jingkai WANG, Wenzhou (CN); Xiang ZHANG, Wenzhou (CN); Yigang LIN, Wenzhou (CN)

(73) Assignee: Wenzhou University, Wenzhou (CN)

(21) Appl. No.: 19/270,517

(22) Filed: Jul. 16, 2025

(30) Foreign Application Priority Data
Mar. 7, 2025 (CN) 202510266299.3

(51) Int. Cl. G06F 30/17; G06T 15/00

(52) U.S. Cl. CPC G06F 30/17; G06T 15/005; G06T 2210/52

(57) ABSTRACT

A scene rendering method and apparatus for a large-scale digital twin model, a device, a medium, and a product are provided. The method includes: reconstructing, in an application phase, for any digital twin model, grid cells based on model information and texture information to determine grid cell data; rendering, in a multi-threaded collaborative grid rendering phase, the model with the reconstructed grid cells as an object, starting a corresponding thread group in a grid shader based on the grid cell data, and constructing a shared cache field in a GPU, where the thread group includes a plurality of sub-threads, and each primitive in the grid cells corresponds to one or more sub-threads; and performing, in a rasterization phase, rasterization processing on the computational results in the shared cache field to determine a rendered scene.

### CROSS-REFERENCE TO THE RELATED APPLICATIONS

This application is based upon and claims priority to Chinese Patent Application No. 202510266299.3, filed on Mar. 7, 2025, the entire contents of which are incorporated herein by reference.

### TECHNICAL FIELD

The present disclosure relates to the field of scene rendering, and in particular to a scene rendering method and apparatus for a large-scale digital twin model, a device, a medium, and a product.

### BACKGROUND

With the rapid development of information technology, digital twin technology has become a key component of Industry 4.0 and is widely used in many fields such as intelligent manufacturing, smart city construction, and complex system simulation. The digital twin technology creates a digital copy of a physical entity to enable real-time monitoring, analysis, and optimization of the status of the entity. However, in large-scale digital twin production scenarios, there are a large number of three-dimensional models, including workshop models, device models, workpiece models, etc. These models are characterized by high precision and large scale, and also have their own corresponding attribute and logical information. Therefore, real-time rendering faces the difficulty of processing huge geometric data, which brings huge technical challenges.

Traditional rendering technology needs to process a large number of model grids and drawing calls when dealing with large-scale scenes, which often leads to low rendering efficiency and cannot meet real-time interaction requirements. Especially in dynamically changing environments, frequent grid update and rendering computation will further increase system burdens, limiting the application scope and effects of digital twin systems. Additionally, existing rendering systems often lack effective and complete optimization strategies and involve huge amounts of data lack of effective sorting when dealing with complex geometric shapes and dynamic objects, leading to performance bottlenecks in a rendering process. For example, in an industrial automation scenario, real-time path planning and simulation of a robot arm twin include a large amount of dynamic data, which requires efficient data interaction and rendering support. However, traditional rendering technology puts a lot of pressure on Center Processing Unit (CPU) computing tasks, which is difficult to meet this requirement well.

In response to the above issues, domestic and foreign scholars have conducted a lot of research in this area. In terms of model data processing, Wei Yixiong et al. adopted a method for simplifying detailed features and reconstructing model structures to achieve ultra-lightweight processing on a geometric model, in order to reduce system operating loads. Liu Huijuan et al. proposed a set of parameter optimization algorithms for Computer Aided Design (CAD) models to perform parametric redrawing on complex pipeline corridor models. Zhou Xiaohua et al. employed a method for pre-caching of model data such that a model can be quickly loaded and rendered to respond to a system. Aidan Fulle et al. used a method of automatically generating model data sets to reduce the amount of data actually used, thereby optimizing data management in a rendering process. The above methods have improved a data amount and a data loading process of model data to meet requirements for rapid system response.

Making full use of parallel capabilities of graphics processing units (GPUs) is also one of ways to improve the rendering efficiency of digital twin systems. In existing research, a method of using GPUs to drive a rendering process is more common, and a GPU drawing method is usually used to accelerate rendering of large-scale scenes. Vivek Kwatra implemented a fast frustum culling algorithm in a GPU kernel to boost culling efficiency. Mochi Xue et al. employed GPU instantiation technology in a virtual space, which greatly improved dynamic sharing scenes. Experts at home and abroad also improve the performance and quality of twin model rendering starting from algorithm optimization and development of new programming architectures. Liu Zhen et al. proposed an accelerated rendering method based on a Compute Unified Device Architecture (CUDA) and designed a corresponding rendering algorithm for control. Jia employed a GPU-accelerated distributed architecture in industrial IoT scenarios to decompose and distribute digital twin simulation and rendering tasks to multiple GPU nodes for parallel processing, achieving efficient real-time simulation in processing large-scale industrial data. Bastian Kuth proposed a GPU-based digital twin framework and dynamic load balancing strategy, which utilized high parallel computing capabilities of GPUs, and can process and simulate large amounts of complex data in a short period of time for real-time simulation of complex systems. The above studies proposed improved rendering methods, but these methods still use original vertices and patches as rendering units, involve numerous rendering threads, and have not made fundamental optimizations to data structures and rendering processes thereof. The specific approaches mainly focus on improving the parallel mode of GPUs. Issues such as complex grid data, inefficient data indexing, and frequent calls still exist. How to improve the rendering efficiency of large-scale scene digital twin systems and achieve real-time, high-precision interaction and management is an important problem that needs to be solved urgently in this field.

### SUMMARY

An objective of the present disclosure is to provide a scene rendering method and apparatus for a large-scale digital twin model, a device, a medium, and a product to solve the problem of low rendering efficiency of a large-scale scene digital twin system.

To achieve the above objective, the present disclosure provides the following solutions.

In a first aspect, the present disclosure provides a scene rendering method for a large-scale digital twin model, including:
reconstructing, in an application phase, for any digital twin model, grid cells based on model information and texture information to determine a grid cell data, where the digital twin model is a model with a closed boundary;
rendering, in a multi-threaded collaborative grid rendering phase, the model with the reconstructed grid cells as an object, starting a corresponding thread group in a grid shader based on the grid cell data, and constructing a shared cache field in a GPU, where the thread group includes a plurality of sub-threads, and each primitive in the grid cells corresponds to one or more sub-threads; direct access between the sub-threads is enabled; the shared cache field is configured to store computational results of the sub-threads; the computational results include grid rendering data, logical and dynamic data, and environmental data; and
performing, in a rasterization phase, rasterization processing on the computational results in the shared cache field to determine a rendered scene.

In a second aspect, the present disclosure provides a scene rendering apparatus for a large-scale digital twin model, including:
a grid cell data determining module, configured to reconstruct, in an application phase, for any digital twin model, grid cells based on model information and texture information to determine a grid cell data, where the digital twin model is a model with a closed boundary;
a grid rendering module, configured to render, in a multi-threaded collaborative grid rendering phase, the model with the reconstructed grid cells as an object, start a corresponding thread group in a grid shader based on the grid cell data, and construct a shared cache field in a GPU, where the thread group includes a plurality of sub-threads, and each primitive in the grid cells corresponds to one or more sub-threads; direct access between the sub-threads is enabled; the shared cache field is configured to store computational results of the sub-threads; the computational results include grid rendering data, logical and dynamic data, and environmental data; and
a rasterization processing module, configured to perform, in a rasterization phase, rasterization processing on the computational results in the shared cache field to determine a rendered scene.

In a third aspect, the present disclosure provides a computer device, including a memory, a processor, and a computer program stored in the memory and executable on the processor, where the processor executes the computer program to implement the scene rendering method for a large-scale digital twin model in any one of the above aspects.

In a fourth aspect, the present disclosure provides a computer-readable storage medium, having a computer program stored thereon, where the computer program, when executed by a processor, implements the scene rendering method for a large-scale digital twin model in any one of the above aspects.

In a fifth aspect, the present disclosure provides a computer program product, including a computer program, where the computer program, when executed by a processor, implements the scene rendering method for a large-scale digital twin model in any one of the above aspects.

According to specific embodiments provided in the present disclosure, the present disclosure discloses the following technical effects. In the present disclosure, the grid cells are reconstructed based on the model information and the texture information, to determine the grid cell data, the data is stored, called, and accessed in the form of the grid cell data, and the vertex rendering order (i.e., the vertex access order list) is optimized based on the model scale and the neighborhood selection in consideration of the close proximity relations of vertices and patches, improving a vertex reuse rate; and a relative differential encoding method is used to re-index the vertices instead of a traditional absolute indexing method, improving data access efficiency.

In the rendering procedure, in the present disclosure an original geometry phase is replaced with the multi-threaded collaborative grid rendering phase, the grid cells are used as objects for model rendering, which abandons a primitive-wise geometry processing method in an original procedure, the corresponding thread is started according to the grid cells in the grid shader, and the shared cache field is set up in the GPU to achieve synchronization and interaction between rendering threads and between twin data computing and rendering data, reducing frequent waiting time of the threads, boosting the efficiency of the GPU processing threads, and improving the rendering efficiency of the large-scale scene digital twin system.

### BRIEF DESCRIPTION OF THE DRAWINGS

To illustrate the technical solutions in the embodiments of the present disclosure or conventional art more clearly, the accompanying drawings required for the embodiments are briefly described below. Apparently, the accompanying drawings in the following description show merely some embodiments of the present disclosure, and those of ordinary skill in the art may still derive other accompanying drawings from these accompanying drawings without the exercise of creative efforts.

FIG. 1 is a flowchart of twin model rendering in the prior art;

FIG. 2 is a flowchart of a multi-threaded collaborative twin model rendering method based on data reconstruction according to some embodiments of the present disclosure;

FIG. 3 is a flowchart of a scene rendering method for a large-scale digital twin model according to some embodiments of the present disclosure;

FIG. 4 is a surface subdivision diagram of an industrial-grade CAD robotic arm model according to some embodiments of the present disclosure;

FIGS. 5A-5B together form a comparison diagram of grid cells constructed based on proximity relations according to some embodiments of the present disclosure, where FIG. 5A is a schematic diagram of a grid geometry structure in an original form; and FIG. 5B is a schematic diagram of a grid structure in consideration of proximity relations;

FIGS. 6A-6B together form a comparison diagram of a reconstructed grid cell composition according to some embodiments of the present disclosure, where FIG. 6A is a schematic diagram of cell data in an original form; and FIG. 6B is a schematic diagram of a reconstructed grid cell data;

FIG. 7 is a schematic diagram of relative differential encoding indexing according to some embodiments of the present disclosure;

FIG. 8 is a basic block diagram of multi-threaded collaborative twin model rendering based on grid data reconstruction according to some embodiments of the present disclosure;

FIG. 9 is a flowchart of thread group creation and sub-thread collaborative management according to some embodiments of the present disclosure;

FIG. 10 is a schematic diagram of a state behavior tree model of a robot in a flexible manufacturing unit according to some embodiments of the present disclosure;

FIG. 11 is a schematic diagram of a structure of a typical miniature circuit breaker;

FIG. 12 is a production scene layout diagram of a miniature circuit breaker production workshop;

FIG. 13 is a rendering example diagram of a twin production workshop for a miniature circuit breaker according to some embodiments of the present disclosure;

FIG. 14 is a comparison chart of average frame rates of rendering solutions according to some embodiments of the present disclosure; and

FIG. 15 is a schematic diagram of a structure of a computer device according to some embodiments of the present disclosure.

### DETAILED DESCRIPTION OF THE EMBODIMENTS

The technical solutions of examples of the present disclosure will be clearly and completely described below with reference to the accompanying drawings in the examples of the present disclosure. Apparently, the examples described are merely some rather than all of the examples of the present disclosure. On the basis of the examples of the present disclosure, all the other examples that would have been obtained by those of ordinary skill in the art without involving any inventive effort shall fall within the scope of protection of the present disclosure.

To make the above objective, features, and advantages of the present disclosure clearer and more comprehensible, the present disclosure is further described in detail below with reference to the accompanying drawings and specific implementations.

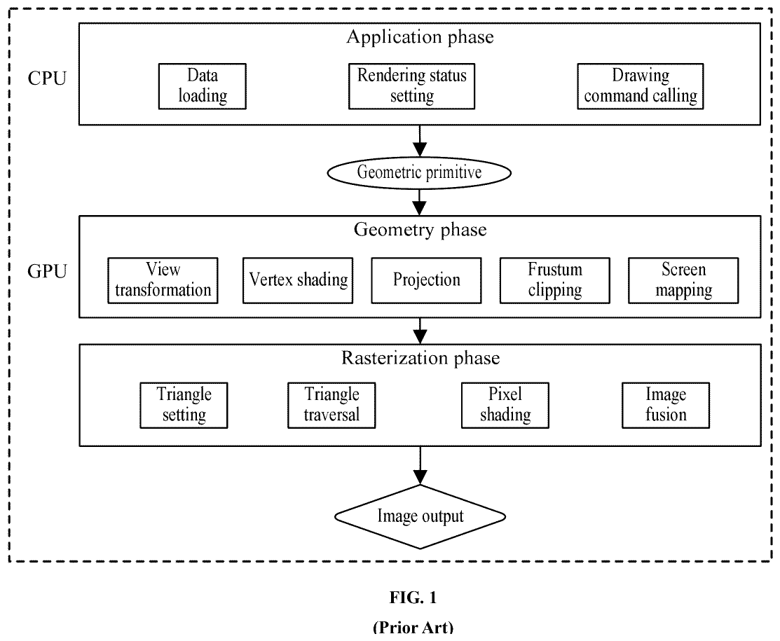

A twin model rendering solution in the prior art is mainly divided into an application phase, a geometry phase, and a rasterization phase, and a procedure thereof is shown in FIG. 1.

1. Application phase: In this phase, a 3D model is preprocessed into a set of triangle patches and vertices to form primitives, which mainly involves geometric transformation, view transformation, and texture coordinate processing of the model to enhance geometric details. Vertex and primitive data are stored in a CPU cache, and corresponding vertex indices are generated for calling. However, in this process, the geometric data is mainly in an original form without compression and optimization, resulting in a large data size and causing pressure for subsequent processing.

2. Geometry phase: In this phase, the primitives generated in the application phase are received and subjected to triangle-wise and vertex-wise operations. A core task is to transform vertex coordinates to a screen space and perform operations such as frustum clipping, occluder generation, and particle system rendering, and then control the primitive information to enter the rasterization phase. This phase relies on the vertex indices for access and operation. Because the original data in the application phase is not processed and optimized, a vertex reuse rate is low, an index data amount is large, and access is disordered, which seriously affect rendering efficiency.

3. Rasterization phase and fragment phase: In the rasterization phase, the primitive data is converted into pixels, including primitive traversal, pixel coverage detection, and vertex clipping. In this phase, the output of the geometry phase is converted into screen pixel mappings, and pixel coverage attributes are determined. In the fragment phase, a plurality of subsamples are blended to obtain a final pixel result. In this phase, a GPU needs to access data stored in a CPU vertex buffer and index buffer. The disordered indices and large size of the original data will lead to frequent redundant interactions between the GPU and the CPU, forming computing bottlenecks.

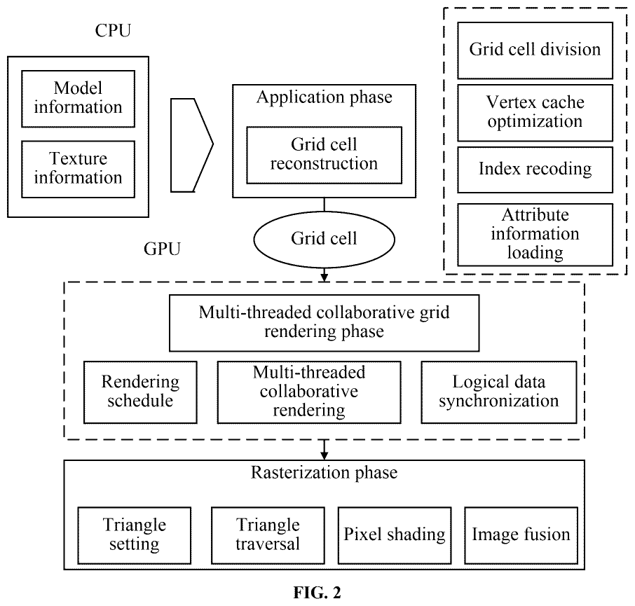

To address the above issue, the present disclosure provides an efficient rendering method for a large-scale digital twin model based on grid data reconstruction. A main procedure is shown in FIG. 2. A rendering data object originates from an original Computer Aided Design (CAD) model, and the model is converted into triangle patch and vertex sets according to inherent modeling logic thereof. These sets are composed of a vertex list and an index list, where the vertex list mainly records spatial positions of the vertices, and the index list specifies vertices that constitute each patch to achieve efficient data calling. The large-scale scene is a scene at the level of millions of twin models.

In the present disclosure, geometric data in an original format is reconstructed, vertices and patches of the model are converted into the grid cell data, the data is stored, called, and accessed in the form of grid cell data, a vertex rendering order is optimized based on a triangle neighborhood selection, improving a vertex reuse rate; and a relative differential encoding method is used to re-index the vertices instead of a traditional absolute indexing method, improving data access efficiency. In a rendering procedure of the present disclosure, the original geometry phase is replaced with a multi-threaded collaborative grid rendering phase, the grid cells are used as an object for model rendering, which abandons a primitive-wise geometry processing method in the original procedure, a corresponding thread is started according to grid cells in a grid shader, and a shared cache field is set up in a GPU to achieve synchronization and interaction between rendering threads and between twin data computing and rendering data, reducing frequent waiting time of the threads and boosting the efficiency of the GPU processing threads.

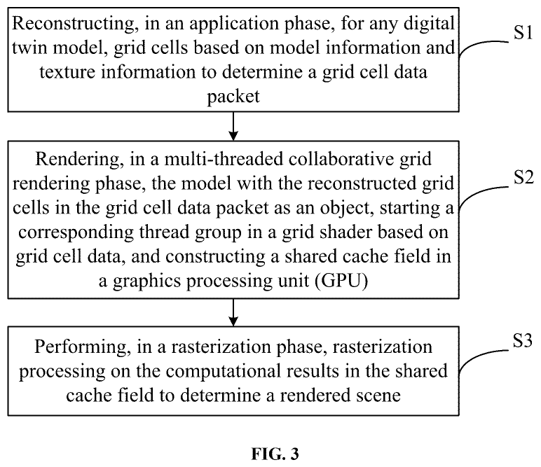

An embodiment of the present disclosure provides a scene rendering method for a large-scale digital twin model. The method is performed by a computer device, and may be performed by a computer device such as a terminal or a server alone, or may be performed by a terminal and a server jointly. In the embodiment of the present disclosure, as shown in FIG. 3, the method includes steps S1-S3.

In step S1 of an application phase, for any digital twin model, grid cells are reconstructed based on model information and texture information to determine a grid cell data. The digital twin model is a model with a closed boundary.

In step S2 of a multi-threaded collaborative grid rendering phase, the model is rendered with the reconstructed grid cells as an object, a corresponding thread group is started in a grid shader based on the grid cell data, and a shared cache field is constructed in a GPU. The thread group includes a plurality of sub-threads, and each primitive in the grid cells corresponds to one or more sub-threads. Direct access between the sub-threads is enabled. The shared cache field is configured to store computational results of the sub-threads. The computational results include grid rendering data, logical and dynamic data, and environmental data.

In step S3 of a rasterization phase, rasterization processing is performed on the computational results in the shared cache field to determine a rendered scene.

In an exemplary embodiment, S1 may be replaced by the following steps.

In step S13, the simplified digital twin model is reconstructed into a plurality of grid cells based on a model scale and a neighborhood selection in consideration of close proximity relations between vertices and patches. Each grid cell includes a set of vertices and a plurality of primitives. The shape of the patch is a triangle.

In step S14, the data information and data formats of the grid cells are reconstructed, and a grid cell data including a variety of information is determined. The grid cell data includes a grid description buffer, a vertex index buffer, a primitive index buffer, and grid attribute information. The grid attribute information includes a logic script, dynamic information, and grid culling for twin control.

In a practical application, a model preprocessing procedure is as follows:

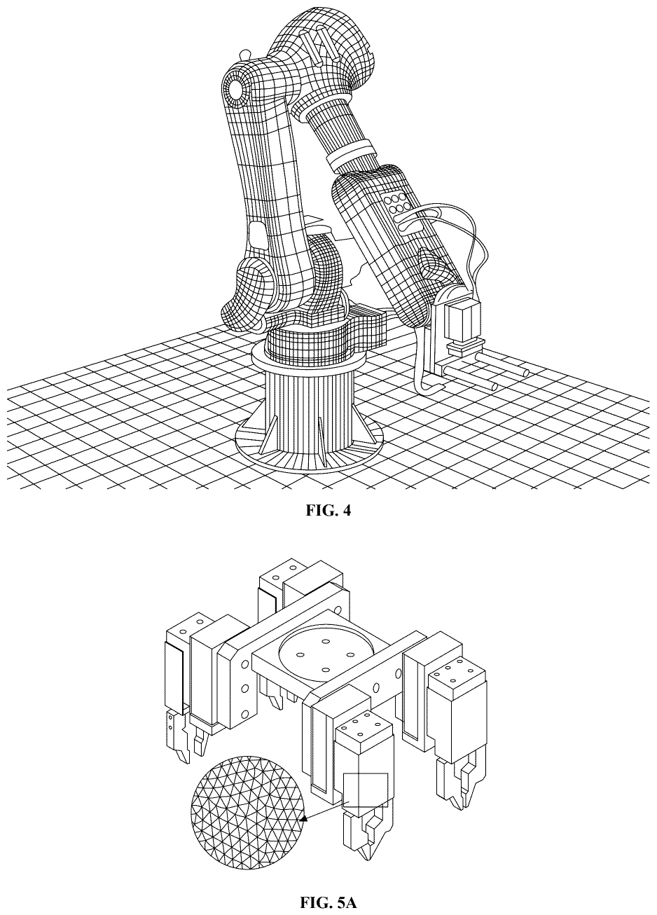

Surfaces of an industrial-grade CAD model require refinement, which will easily generate a large number of patches and vertices. As shown in FIG. 4, in order to improve rendering efficiency, the model needs to be preprocessed first. The present disclosure adopts a model simplification strategy of a collapse algorithm to reduce the number of patches and vertices.

For a digital twin model (with a closed boundary, according to which space may be divided into two parts: inside the model and outside the model), the model is collapsed so that two triangular patches, three edges, and one vertex may be removed. A collapse cost is calculated to ensure the smallest possible impact on the appearance of the model.

In an exemplary embodiment, after S14, the following steps are further included:

In step S15, based on a vertex set and a triangle set in the grid cells, vertices in the vertex set are initialized, and vertex degrees are calculated.

In step S16, information parameters are defined based on the vertex degrees. The information parameters include a vertex cache, a maximum capacity of the vertex cache, a triangle output list, and a candidate triangle set. An initial value of the candidate triangle set is the triangle set. The triangle output list is a vertex access order list.

In step S17, a next triangle with the largest degree of overlap with a vertex in the vertex cache is selected from the candidate triangle set.

In step S18, each vertex in the next triangle is traversed, a vertex that is not in the vertex cache is added to the vertex cache, and the vertex access order list is updated based on the maximum capacity of the vertex cache, until all triangles in the candidate triangle set are traversed, to determine a final vertex access order list.

In step S19, a vertex index order of triangles is regenerated based on the final vertex access order list.

In a practical application, a grid data reconstruction procedure of the model is as follows:

Commonly used digital twin 3D models include models with file format of Wave front.obj, Graphics Language Transmission Format (glTF), Universal Scene Description (USD), etc. These models are usually composed of disordered vertices and patches, and the vertices and indices are connected in a random manner, which is not conducive to data access and calling. To resolve this issue, the grid data needs to be reconstructed. A grid is generally defined as a group of geometric vertices, where each triple of consecutive vertices forms a triangle, which is used to represent two-dimensional and three-dimensional geometric models.

In existing methods, for grid data, a plurality of vertices and patches are usually packed in a fixed number without considering spatial orders and proximity relations of the vertices and patches. In fact, when a model grid is constructed, geometric vertices thereof should be close to each other, indices of the grid should be constructed according to proximity relations of matching vertices, and normal directions of the patches should be as consistent as possible to minimize issues of repeated vertex calling and data jumping access caused by non-adjacent spatial positions of patches, which would otherwise cause computational burdens.

The present disclosure proposes a data reconstruction method based on grid cells, and specific reconstruction includes two parts. First, when a grid is constructed, close proximity relations of geometric vertices and patches are taken into consideration. According to a scale of the model and a neighborhood selection, a fixed number of vertices and patches are selected for multi-level combination, and grid cells of different sizes are generated based on a collapse cost formula

$$cost ( u , v ) = ‖ u - v ‖ {max}_{f ∈ {T}_{u}} \{ {min}_{n ∈ {T}_{uv}} \{ ( 1 - f \cdot normal \cdot n \cdot normal ) \div 2 \} \}$$

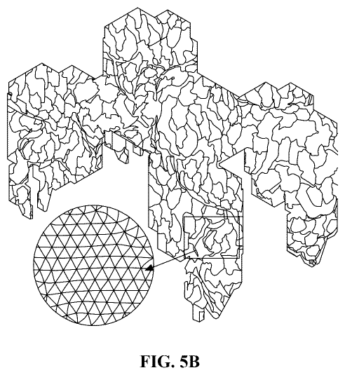

in the collapse process, where u and v represent two points in a pair, cost (u, v) represents the collapse cost, Tᵤ is a set of all patches proximate to u, Tᵤᵥ is a set of all patches around u and v, and f.normal and n.normal represent normal vectors of Tᵤ and Tᵤᵥ, respectively. As shown in FIG. 5B, in the reconstructed grid cells, each cell includes a set of vertices and a plurality of primitives. These primitives share vertices in the grid cells, and the vertices may be reused efficiently.

In addition, compared with FIG. 5A, it may be found that vertices and patches of the reconstructed grid cells are evenly and concisely distributed, and redundant patches and vertices are optimized, thereby representing the geometric model more concisely and reducing resource consumption of a subsequent rendering procedure.

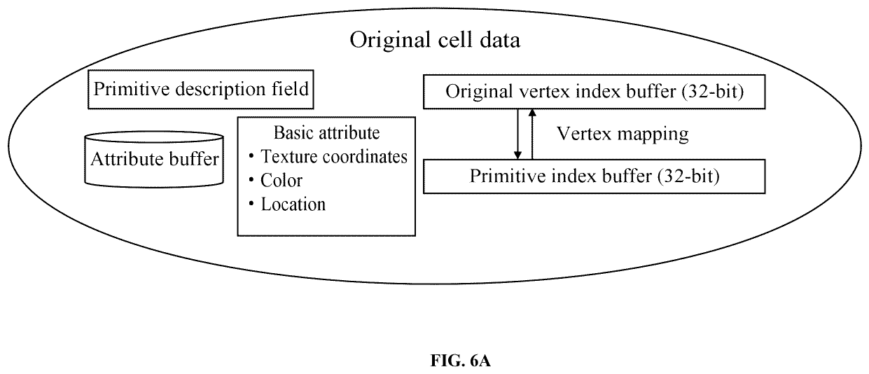

After the grid is reconstructed, data information and data format of the grid cells need to be redefined and constructed, to construct original geometric unit data into grid cell data including a variety of information, a format of which is shown in FIG. 6A. In FIG. 6B, a grid description buffer is constructed and numbered (M₀, M₁, etc.), which replaces a traditional primitive description field, and is used to store key geometric metadata. A vertex index buffer and a primitive index buffer are constructed, and relative indexing are used instead of absolute indexing, so that data bits are shorter and resource overheads are reduced. On the basis of the original basic attribute data, grid attribute data is constructed, and a logic script, dynamic information, grid culling, and other information that support real-time mapping computing of a twin are added. These extended information serves logical computing and data processing of the twin, and provides support for grid culling, improving overall rendering efficiency and dynamic adaptability. Functions of respective parts of the reconstructed grid cell data in FIG. 6B are as follows:

Grid description buffer: The grid description buffer is used to mainly store key description information of the divided grid, including a starting vertex index, the number of vertices, a primitive starting index, and the number of primitives, providing the GPU with a geometric structure description of the grid.

Vertex index buffer: The vertex index buffer is used to store index information of vertices, which is arranged in the order of constructed grid cells. Relative indexing is used to replace original absolute indexing and therefore a 16-bit unsigned integer may be used for data storage.

Primitive index buffer: The primitive index buffer is used to store primitive indices, and uses 8-bit unsigned integers for data storage to index and call primitive information.

Grid attribute information: The grid attribute information includes a logic script, dynamic information, grid culling, and other information for twin control. The logic data script includes information such as simulation computing and internal logical constraints of the twin. The dynamic information includes positions and motion statuses of the grid cells. The grid culling information is a key component of frustum culling, which includes a grid position, size, etc., and is used to cull the grid outside a frustum.

After the grid cells are reconstructed, it is necessary to optimize vertex storage and calling orders, establish a corresponding indexing strategy, maximize reuse of vertices in the triangle patches, improve a vertex reuse rate, and reduce the number of vertex loading times in threads. In the present disclosure, a Tipsify algorithm is used to optimize the vertex calling order, a triangle list of vertices is constructed based on proximity relations, a vertex cache hit rate is calculated, the triangle indices with a high cache hit rate are selected as a new vertex index order, and accordingly updates and iterations are performed to improve rendering efficiency. Specific steps are as follows:

In step 1, the grid data is input, which includes a vertex set V and a triangle set T, a vertex v is initialized, and a vertex degree D(v) thereof is calculated according to formula (1):

$$D ( v ) = {\sum }_{t ∈ {T}_{v}} 1 , \qquad ( 1 )$$

where Tᵥ represents a set of triangles associated with each vertex v, and D(v) represents a degree thereof, which means the number of unprocessed triangles connected to the vertex v. When a triangle t belongs to Tᵥ, a corresponding count value is 1, and a final sum is the degree of vertex v.

In step 2, a vertex cache P with the maximum capacity of C is defined for storing a current active vertex. An empty triangle output list S is defined for recording an access order of vertices. A candidate triangle set U is defined, whose initial value is a set of all triangles T.

In step 3, a next triangle t is selected from the set U, where a triangle with the greatest overlap with vertices in the cache is selected in priority. If there is no reusable vertex, a triangle including a vertex v with the largest degree is selected. At the same time, the triangle t is removed from U and is marked as processed.

In step 4, each vertex v in the triangle t is traversed. If v is not in the cache P, v is added to the cache P. If the cache exceeds the capacity C, the earliest added vertex is removed and the vertex v is added to the vertex access order list S (if not recorded).

In step 5, step 3 and step 4 are repeated until all triangles are processed. According to the vertex access order list S, the vertex index order of triangles is regenerated, and the vertex access order list is output as a result.

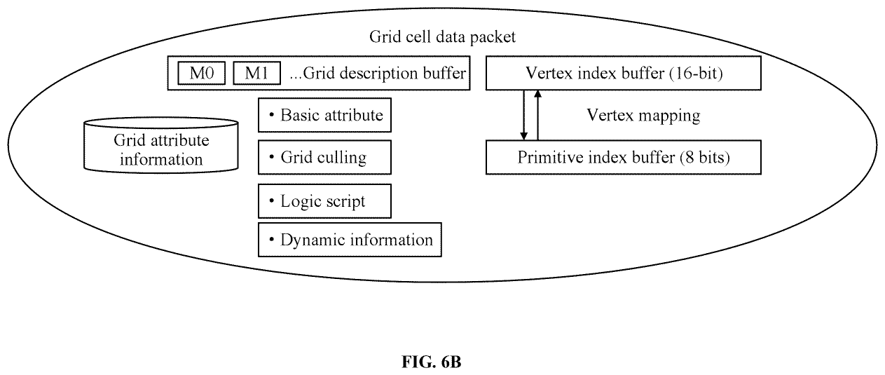

For a large-scale scene, model patch and vertex data are large in scale, and vertices need to be indexed and called frequently. In order to boost computing efficiency, in the present disclosure, a relative differential encoding method is adopted instead of a traditional absolute indexing method, and a basic principle thereof is shown in FIG. 7. An upper part of FIG. 7 is the vertex index buffer, which includes all vertex indices in the grid that are sorted in an order within the grid. In FIG. 7, numbers 156, 157, 158, etc. are used to represent the vertex index sorting. In the reconstructed grid cells, internal vertices thereof are arranged sequentially and the number of vertices is limited, and therefore the vertices may be sequentially encoded inside the grid cells with less storage bit width to reduce resource consumption. In the primitive index buffer in FIG. 7, relative indexing may be employed to locate vertices and construct primitives. For example, three numbers 0, 1, and 2 are used to locate vertices, which greatly reduces the amount of data.

In an exemplary embodiment, S2 may be replaced with the following steps.

In step S21, the grid cell data is processed by using a task shader in the multi-threaded collaborative grid rendering phase, to determine the logical and dynamic data and grid image data.

In step S22, the grid image data is loaded in the grid shader, and the grid image data is reconstructed into a plurality of pieces of grid cell data.

In step S23, the corresponding thread group is started with the grid cell data as an object, and a plurality of sub-threads are allocated to each primitive in the grid cell data, to determine grid rendering data. Each sub-thread independently performs vertex transformation, attribute computing, triangle culling, and rendering tasks.

In step S24, the logical and dynamic data is processed by using a plurality of thread groups based on a compute shader, to determine the logical and dynamic data and the environmental data.

In step S25, the shared cache field is constructed in the GPU, and the grid rendering data, the logical and dynamic data, and the environmental data are stored into the shared cache field.

In a practical application, in the rendering procedure shown in FIG. 1, in the geometry processing phase, operations such as vertex transformation and screen mapping in the shader need to be performed in a relatively fixed order. The primitive and vertex data need to be processed serially in sequence. Threads cannot collaborate with and edit each other, which limits rendering efficiency. A fundamental reason therefor is that the traditional rendering procedure uses primitives as basic processing units, and such data granularity limits parallel processing effects, and causes frequent waiting and calling issues between threads.

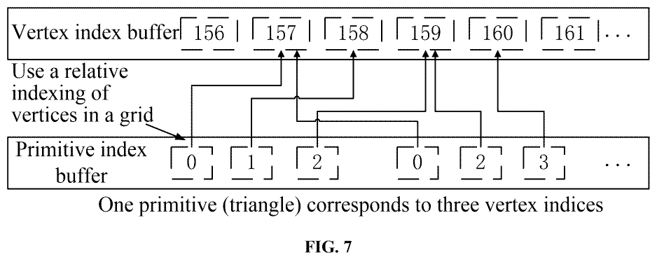

The present disclosure proposes a multi-threaded collaborative twin model rendering method based on grid data reconstruction, and a basic framework thereof is shown in FIG. 8. A traditional method based on primitives as basic processing units is reconstructed into a method based on grid cells as basic units. In FIG. 8, the grid cell data is divided into grid graphic data and logical and dynamic data after being processed by the task shader. The grid graphic data is loaded in the grid shader, and the logical and dynamic data are processed in the compute shader.

According to the above data reconstruction method based on grid cells, the grid graphic data is reconstructed into a number of grid cell data, and a corresponding thread group is started for each cell, and the thread group further allocates a plurality of sub-threads to each internal primitive data. Each sub-thread independently performs vertex transformation, attribute computing, triangle culling, and other rendering tasks. The shared cache field is constructed in the GPU, and computational results of the sub-threads are stored in the shared cache field. The sub-threads may directly access data of each other without an external video memory, achieving efficient data exchange. In order to ensure synchronization between parallel threads, a thread barrier synchronization mechanism is designed. First, after vertex transformation is completed, all the threads wait synchronously to ensure that data is consistent when entering a primitive culling phase. Then, after primitive culling is completed, all the threads are synchronized again to ensure that the data is consistent when entering an output phase. Finally, the processed data will be aggregated into a global cache to enter a subsequent rasterization processing phase, to finally complete rendering.

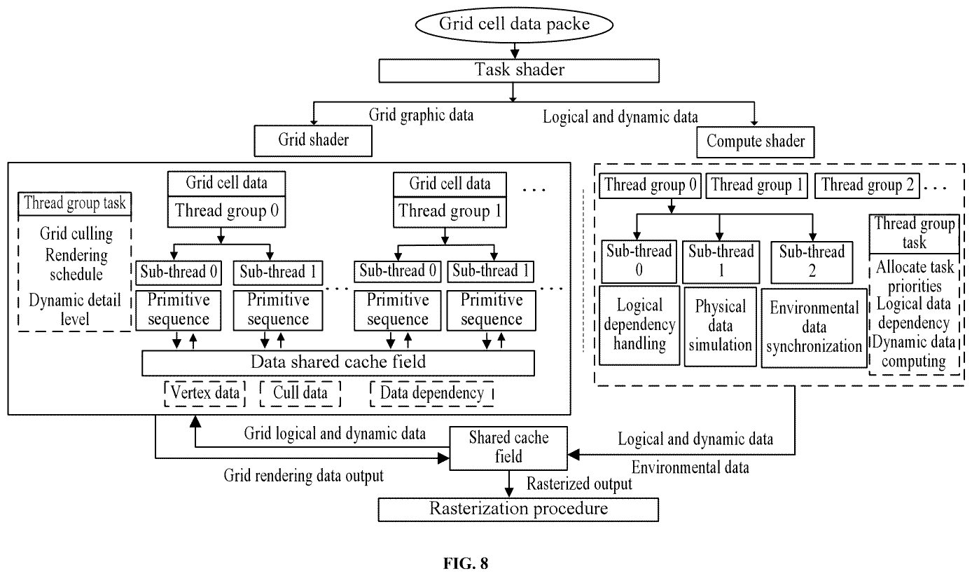

The task shader is responsible for generating, scheduling, and allocating rendering tasks, and processing a rendering task relationship according to priorities of the rendering tasks to avoid resource contention and errors. FIG. 9 shows a specific procedure of thread group creation and sub-thread collaborative management.

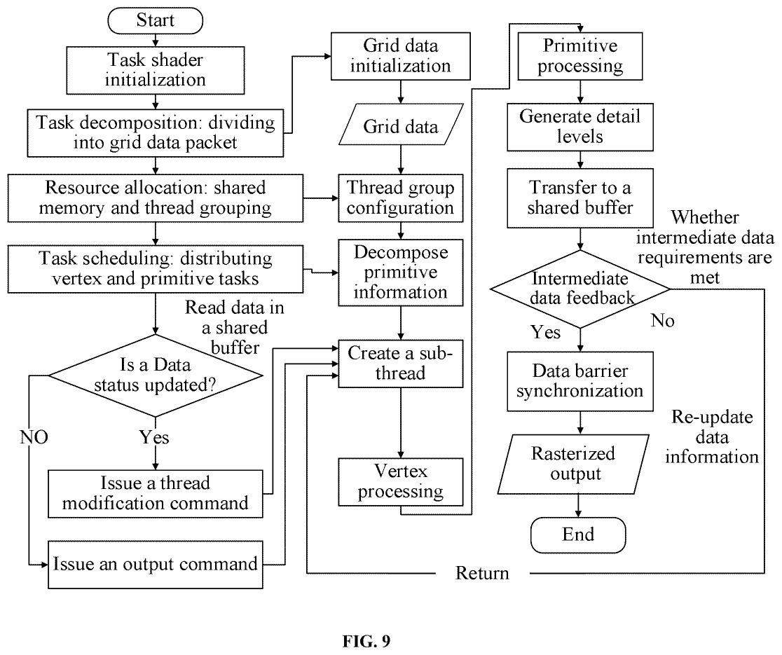

In addition, the twin model involves computing of dynamic data and logical data, such as physical simulation, logical dependency, and environmental feedback. Using production modeling of a robot in a flexible manufacturing unit as an example, a state behavior tree is used to describe a production state of a digital twin thereof, as shown in FIG. 10. The state behavior tree includes a job status, data dependency, a waiting status, interaction information, and an exit status. Each state is composed of specific sub-elements. After a specific condition is met, the robot generates corresponding data dependency and performs a next job status transition based on a completion status of a previous process. At the same time, interactive information of the system needs to receive external signals and feedback, which has high priorities. When the digital twin receives an interactive signal, the digital twin needs to parse and perform a related operation first, and then enter a job state after completion.

In order to effectively handle dynamic data and logical compute issues of the twin, the compute shader in the GPU is used for compute and management in FIG. 8, and a corresponding thread group is started for each type of logical data for parallel computing. In order to synchronize static geometric model rendering data with the logical and dynamic data, a data sharing cache field is constructed in the GPU, and intermediate computational results of the grid shader are saved in the shared cache field for subsequent computing. At the same time, after the compute shader completes computing of the logical and dynamic data, the compute shader outputs an updated job status, grid position, direction, and other information, and stores them synchronously in the shared cache field for the rendering thread in the grid shader to call to render and form a new geometric model and job status, ultimately achieving efficient synchronization of the static model rendering and the dynamic and logical data, and supporting real-time dynamic performance and interaction of the digital twin in a large-scale scene.

In the present disclosure, the original geometric data is reconstructed into the grid cells, the data inside the cells are re-indexed, the vertex drawing order is optimized according to priorities, the vertex reuse rate is increased, and the number of drawings is reduced. In terms of GPU parallel computing, based on the reconstruction of grid data, the multi-threaded collaborative grid rendering method is designed to transfer the computing of the logical data and dynamic data in the twin model from the CPU to the GPU, and use the shaders to optimize the processing of rendering tasks and the computing of twin data. This method eliminates redundant threads, and completes calling of drawing instructions in the GPU, and while completing the rendering, synchronously completes the computing of dynamic twin data by setting up cache fields, so as to reduce system interaction delays. Finally, a digital twin workshop system for a miniature circuit breaker is used as an example for verification, to conduct a comparative study on indicators such as system operating efficiency, rendering effects, and CPU/GPU execution efficiency.

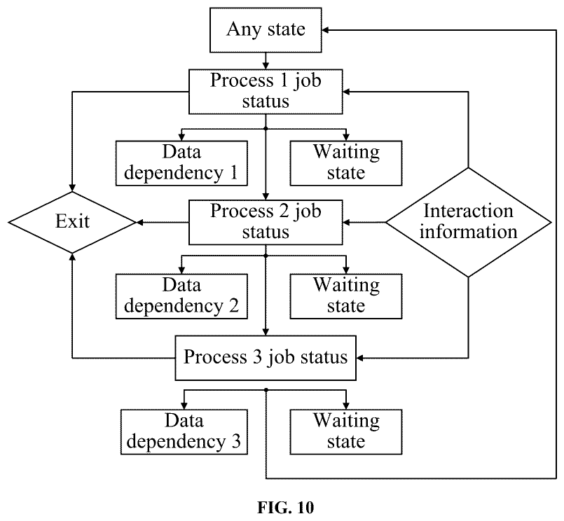

A miniature circuit breaker is a switching apparatus that can close, carry, and interrupt a current in a circuit. As shown in FIG. 11, a basic structure of the miniature circuit breaker is relatively complex and includes many parts, including a handle, a magnetic system, a thermal system, a tripping button, an arc extinguishing chamber, and other components.

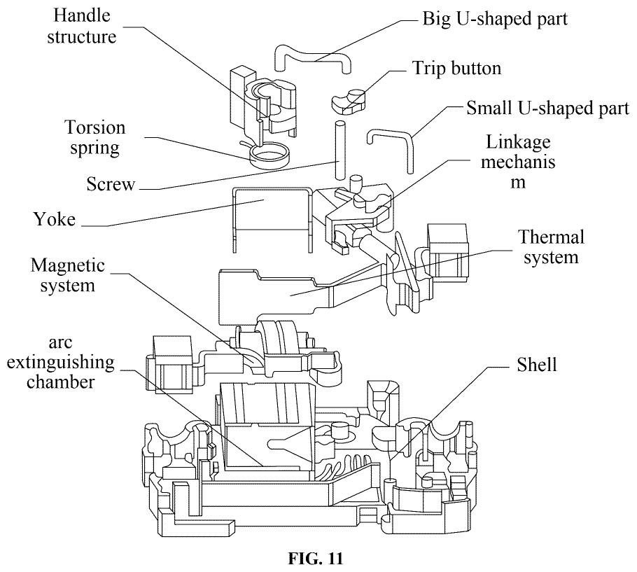

A daily output of miniature circuit breakers is very large. An output of a common assembly line exceeds 20,000 per day. A layout of a twin workshop system for digital manufacturing of miniature circuit breakers is shown in FIG. 12. A complete production line includes two mirror assembly lines and one inspection line. The workshop is provided with a warehousing model and corresponding mapping models such as production line apparatuses. The production line includes 22 sets of devices and 210 manufacturing modules. A manufacturing process involves 6,350 logical assembly actions and 4,312 inspection actions. A process flow includes 18 process flows such as automatic assembly, multi-stage riveting, and laser marking. The number of models is huge. Using the assembly line in FIG. 12 as an example, the total number of models reaches 48,064, and the number of patches is as high as 46.1 million, among which the number of dynamic models that need to participate in logical motion computing is as high as 24,570. Each dynamic model is associated with corresponding logical constraints and dynamic data, which brings great challenges to efficient rendering of twin models and real-time interaction of twins.

In order to model a physical manufacturing process of the circuit breaker workshop, in the present disclosure, a geometric model physical driving engine that accurately maps the real process is constructed. According to collected dynamic model information, dynamic production logical modeling of the production line is implemented through state machine, collision detection, and running logic control code computing. A logical control program for the twin model is based on real-time data and status changes within the scene, helping the system dynamically adjust operations of the production line to ensure that each link can operate efficiently and accurately.

In terms of digital twin workshop model rendering, in the present disclosure, geometric model data of the circuit breaker workshop is collected through embedded data controllers, and a geometric modeling method is employed to complete geometric data modeling of the digital twin workshop. In order to resolve the issue of excessive patches in an original geometric model, in the solution, the lightweighting processing is performed on three-dimensional models of the workshop objects. First, in the present disclosure, scenes and models of the target circuit breaker workshop are classified, and then the scene models further are classified according to scales of the models. For large-scale models, a simpler grid division is adopted to reduce unnecessary computing amounts. For small-scale models, such as mechanical grippers and parts, a refined griding strategy is adopted to reduce maximum numbers of vertices and patches in the grid to ensure that the digital twin can be rendered with maximum precision and accuracy.

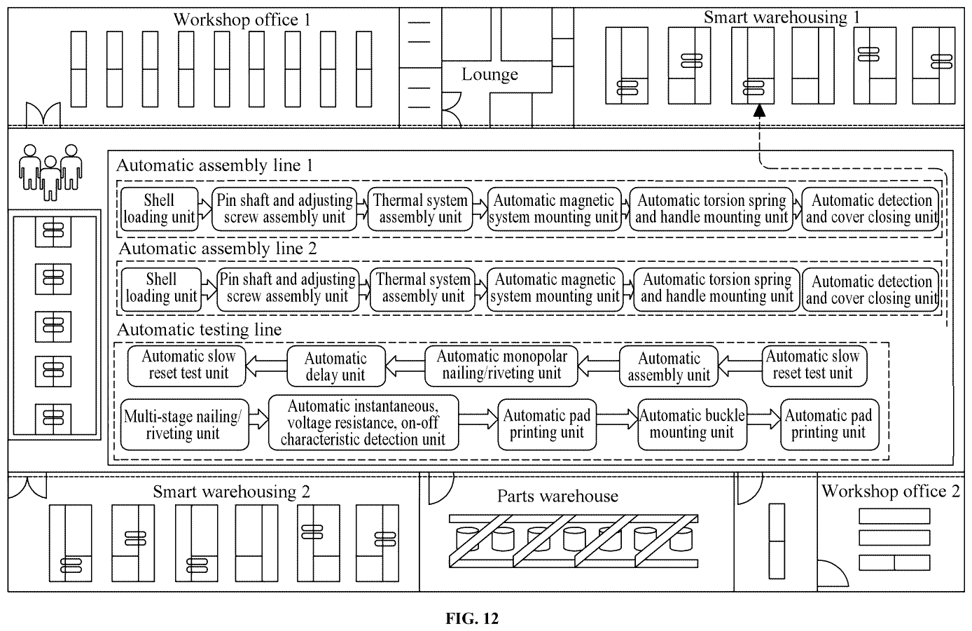

Finally, the aforementioned efficient model rendering method based on grid data reconstruction is employed for the processed workshop digital twin model, to achieve high real-time and high-quality digital twin workshop rendering effects, as shown in FIG. 13.

In order to compare and verify performance of the constructed digital twin workshop system, in the present disclosure the proposed efficient rendering method for the digital twin workshop is verified based on a Unity® 3D platform in a hardware environment of Intel® Core™ i7 10510 processor and Geforce RTX™ 2080 graphics card. The collaborative rendering solution based on data reconstruction proposed in the present disclosure is compared with a traditional method without data reconstruction, in which computational results of units such as automatic nailing, automatic pad printing, and automatic detection are compared respectively. Comparison results are shown in Table 1. Two indicators, an average cache hit rate of vertices and an average vertex call index, are compared respectively. The average cache miss rate F refers to a ratio of cache hits to total accesses among all cache access attempts. The higher the cache hit rate, the better the data retrieval efficiency. The average number of vertex calls refers to an average number of times each vertex is accessed in a rendering process. The closer the data range is to 1, the higher the vertex data utilization efficiency.

The average cache miss rate F may be calculated using the following formula:

$$F = \frac{{N}_{c}}{{N}_{c} + {N}_{m}} \qquad ( 2 )$$

In the formula, N_{c} represents the number of access hits, and Nₘ represents the number of access misses. Table 1 is a comparison table of optimization effects of the vertex cache based on model grid cell reconstruction. From Table 1, it can be seen that in the rendering solution with data reconstruction, the average vertex cache hit rates are all around 0.7-0.86, and the average numbers of vertex calls are all around 1. Both indicators have been greatly improved compared with the technical solution without data reconstruction, especially the average number of vertex calls, the efficiency of which is close to twice that of the traditional solution. The efficiency has been greatly improved.

TABLE 1

| | | Average | Average | Average |
|---|---|---|---|---|
| | Average | cache | number | number of |
| | cache | hit rate in | of vertex | vertex calls in |
| | hit rate in | solution of | calls in | solution of the |
| | traditional | the present | traditional | present |
| Unit name | solution | disclosure | solution | disclosure |
| Automatic | 0.46 | 0.76 | 2.3 | 1.1 |
| nailing unit | | | | |
| Automatic | 0.43 | 0.83 | 2.6 | 1.3 |
| pad printing | | | | |
| unit | | | | |
| Automatic | 0.36 | 0.86 | 2.7 | 1.3 |
| detection unit | | | | |

In order to compare data amounts and data scales, data amounts, data amount compression rates, and vertex index compression ratios of three units of automatic nailing, automatic pad printing, and automatic detection are compared respectively. Table 2 is a comparison table of optimization effects of geometric data based on model grid cell reconstruction. The results are shown in Table 2. It may be seen from the table that after the model is subjected to grid data reconstruction, the data amount is significantly reduced, and the data amount compression rate reaches about 50%. In the present disclosure the relative indexing is employed to replace the traditional absolute indexing method; therefore, the scale of index data is also greatly reduced. As shown in Table 2, the compression ratios of the automatic nailing unit and the automatic detection unit are 55% and 51%, respectively, while the automatic pad printing unit has the highest compression ratio, reaching 57%. These data show that the present disclosure greatly improves the storage efficiency of model data and reduces data transmission costs.

TABLE 2

| | | | Data | Vertex |
|---|---|---|---|---|
| | Data amount | Data amount | amount | index |
| | before model | after model | compres- | compres- |
| | reconstruction/ | reconstruction/ | sion | sion |
| Unit name | Mb | Mb | ratio | ratio |
| Automatic | 520.32 | 231.53 | 55.5% | 55% |
| nailing unit | | | | |
| Automatic | 234.55 | 116.84 | 50.19% | 57% |
| pad | | | | |
| printing unit | | | | |
| Automatic | 283.44 | 148.63 | 47.56% | 51% |
| detection | | | | |
| unit | | | | |

In order to evaluate advantages of the present disclosure in actual rendering effects of the twin model, the solution (marked as Solution A) proposed in the present disclosure is compared with the traditional solution (Solution B) without data reconstruction and a GPU instantiation parallel rendering solution (Solution C). The GPU instantiation parallel rendering solution is a relatively outstanding rendering method for most existing twin scenes, and employs a CPU/GPU parallel computing method, in which rendering commands are directly triggered by a GPU and internal parallel processing capabilities of the GPU are utilized to complete rendering operations including occlusion culling, lighting computing, and result output, aiming to improve rendering performance. In the present disclosure frame rates (i.e. frames per second (FPS)), thread batches, and CPU/GPU time consumption indicators of the three solutions are compared. The FPS is a frequency of picture updates per second when a scene is drawn. The higher the frame rate, the smoother and more realistic the picture is. A threshold value thereof is generally 30 fps. When the frame rate reaches 75 fps, rendering quality is relatively good.

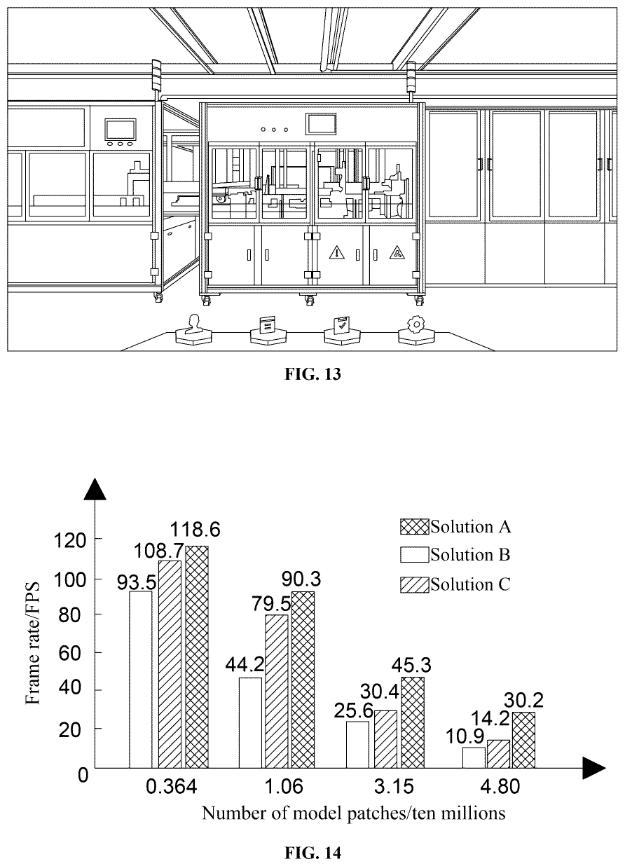

As shown in FIG. 14, in a scene with 3.64 million model patches, the three solutions all have a frame rate of more than 75, which basically meets visualization requirements of the twin system. As the number of patches in the scene model continues to increase, the number of rendering frames continues to decrease. In a scene with 48 million patches, only Solution A can reach 30 fps, which can meet scene interaction requirements. The rendering solution proposed in the present disclosure is Solution A. In scenes with 10.6 million, 31.5 million, and 46.1 million patches, the FPSs thereof reach 90.3, 45.3, and 30.2 fps, respectively. Compared with the traditional Solution B, the frame rates are all doubled or more, achieving significant optimization effects. Compared with the instantiation Solution C, the effect of Solution A is not much different in small-scale scenes with 3.64 million patches, both of which are more 100 fps. However, as the number of patches increases, the scene frame rate of Solution C drops significantly, and Solution A of the present disclosure performs better than Solution C. In the scene with 46.1 million patches, Solution A reaches a frame rate of 30.2 fps, which is about 2 times higher than 14.2 fps of Solution C, further confirming optimization effects thereof on processing large-scale scenes.

Table 3 is a performance comparison table of the solution compared with the traditional rendering solution and the GPU instantiation rendering solution. Table 3 compares performance of the three solutions in terms of batches, CPU time consumption, and GPU time consumption. The batches refer to batches of calls made by the CPU to render objects in the graphics rendering process. The larger the number of batches, the higher the rendering load. It may be seen from Table 3 that as the complexity of the scene model increases, the number of batches increases accordingly. In different scenes, the three indicators of Solution A of the present disclosure are all reduced to varying degrees compared with the traditional solution B. Especially in the scenario with 46.1 million model patches, the optimization effects are obvious. The number of batches is reduced by 2,199 compared with Solution B, the CPU time is reduced to 28 milliseconds, and the GPU time is reduced to 19 milliseconds, which show that hardware performance has been significantly improved, the computational burden of the CPU has been reduced, and the efficiency of the GPU has been enhanced.

TABLE 3

| Model | Batches | | | CPU time | | | | GPU time | | | | |
|---|---|---|---|---|---|---|---|---|---|---|---|---|
| patch | Solution | Solution | Solution | Solution | | Solution | Solution | Solution | | Solution | Solution | |
| number | A | B | C | A | | B | C | A | | B | C | |
| 280,000 | 95 | 352 | 110 | 8 | ms | 13 ms | 10 ms | 9 | ms | 13 ms | 9 | ms |
| 3.64 | 307 | 708 | 425 | 12 | ms | 18 ms | 13 ms | 11 | ms | 15 ms | 12 | ms |
| million | | | | | | | | | | | | |
| 10.6 | 938 | 1589 | 1264 | 17 | ms | 28 ms | 23 ms | 13 | ms | 25 ms | 20 | ms |
| million | | | | | | | | | | | | |
| 31.5 | 1986 | 2506 | 2250 | 21 | ms | 48 ms | 26 ms | 15 | ms | 28 ms | 21 | ms |
| million | | | | | | | | | | | | |
| 46.1 | 23,860 | 26,059 | 25,037 | 28 | ms | 62 ms | 49 ms | 19 | ms | 46 ms | 25 | ms |

million

Both Solution A of the present disclosure and Solution C adopt a parallel architecture, and both have significant improvements in various indicators compared to the traditional Solution B. In addition, when the number of model patches is small, the performance of the two parallel solutions is similar and the difference therebetween is not obvious. However, during processing of large-scale scenes, the rendering efficiency of the instantiation Solution C begins to reach bottlenecks, while Solution A of the present disclosure shows better performance. In particular, in the large-scale scene with 46.1 million model patches, Solution A of the present disclosure reduces 1,177 thread batches compared to Solution C, effectively reducing the number of redundant threads. In terms of hardware performance indicators, compared with the instantiation Solution C, Solution A of the present disclosure optimizes CPU time by 43% and GPU time by 23%, which fully demonstrates the superiority of Solution A of the present disclosure in processing large-scale scenes.

The present disclosure proposes a novel and efficient rendering method for a large-scale digital twin model based on grid data reconstruction to address the issues of large amounts of rendering data and high computing pressure in the large-scale production scenario of the digital twin workshop. First, the memory-friendly grid data structure is reconstructed to effectively reduce the data size and the number of memory calls. In addition, the multi-threaded collaborative rendering solution based on grid data reconstruction is established, in which the grid threads are dynamically configured, and the logical actions and the rendering data are dynamically synchronized in the GPU, improving real-time feedback effects of the rendering data. Comparative experiments show that in the tests of digital twin workshop production scenarios of different scales, while maintaining high-quality rendering effects, the proposed method reconstructs the rendering-friendly grid data structure, the number of vertex calls remains at around 1, and the vertex cache hit rate is close to 80%. Compared with traditional methods, the average rendering frame rate of the present disclosure solution is increased by up to 2.8 times, the CPU time consumption is reduced by 20%, and the GPU time consumption is reduced by 40%, achieving an effect of hardware performance optimization. When the rendering scale is 46 million patches and 48,064 models, the rendering frame rate remains stable at 30 fps, meeting smoothness requirements perceived by the human eye. The CPU takes only 28 ms and the GPU takes only 19 ms, meeting rendering requirements in large-scale digital twin scenarios.

Based on the same inventive concept, the embodiments of the present disclosure further provide a scene rendering apparatus for a large-scale digital twin model for implementing the scene rendering method for a large-scale digital twin model involved above. An implementation solution to the problem provided by the apparatus is similar to the implementation solution disclosed in the foregoing method. Therefore, for specific limitations in the scene rendering apparatus embodiments for one or more large-scale digital twin models provided below, reference may be made to the limitations of the scene rendering method for a large-scale digital twin model above, and details will not be repeated herein.

In an exemplary embodiment, a scene rendering apparatus for a large-scale digital twin model is provided, including:
a grid cell data determining module, configured to reconstruct, in an application phase, for any digital twin model, grid cells based on model information and texture information to determine a grid cell data, where the digital twin model is a model with a closed boundary;
a grid rendering module, configured to render, in a multi-threaded collaborative grid rendering phase, the model with the reconstructed grid cells as an object, start a corresponding thread group in a grid shader based on the grid cell data, and construct a shared cache field in a GPU, where the thread group includes a plurality of sub-threads, and each primitive in the grid cells corresponds to one or more sub-threads; direct access between the sub-threads is enabled; the shared cache field is configured to store a computational results of the sub-threads; the computational results include grid rendering data, logical and dynamic data, and environmental data; and
a rasterization processing module, configured to perform, in a rasterization phase, rasterization processing on the computational results in the shared cache field to determine a rendered scene.

For a digital twin system that includes large-scale scenes, efficient rendering of the scenes is a key to achieving real-time interaction of the system. The large-scale scenes have complex model patches, a large number of models, and numerous logical relationships, which may easily restrict improvement in real-time and interactive performance of the twin system. The present disclosure proposes a novel and efficient rendering method for a large-scale digital twin models based on grid data reconstruction, including grid cell data reconstruction and a grid multi-threaded collaborative twin model rendering system based on reconstructed data. In order to reconstruct grid data, vertices and patches of the model are converted into grid cells, and the grid is indexed and re-encoded and optimized for drawing to reduce an amount of model rendering data and memory usage. Based on the grid data reconstruction, a multi-threaded collaborative grid rendering method is constructed. The reconstructed grid cells are used as rendering data nodes to start threads. A thread collaborative method is used to complete effective configuration of rendering resources. A rendering process is completed under driving of a GPU, which improves GPU parallel efficiency. In addition, logical computing of a twin physical mechanism is completed in a shader, and synchronization of twin data and visualization process data is completed in a shared cache field, which improves model rendering efficiency. A comparative study was conducted using a miniature circuit breaker digital twin workshop system as a case study. The results show as follow. The rendering solution proposed in the present disclosure, while maintaining high-quality rendering effects, increases the average rendering frame rate by up to 2.8 times, reduces the CPU time consumption by 20%, and reduces the GPU time consumption by 40%, as compared to traditional methods when processing scenes with large-scale dynamic objects, thereby effectively improving rendering performance.

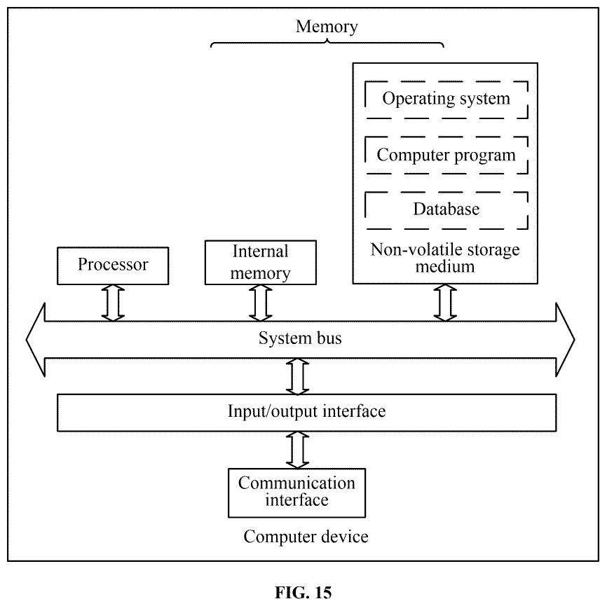

In an exemplary embodiment, a computer device is provided, as shown in FIG. 15. The computer device may be a server or a terminal. The computer device includes a processor, a memory, an input/output (I/O) interface, and a communication interface. The processor, the memory, and the input/output interface are connected via a system bus, and the communication interface is connected to the system bus via the input/output interface. The processor of the computer device is configured to provide computing and control capabilities. The memory of the computer device includes a non-volatile storage medium and an internal memory. The non-volatile storage medium stores an operating system, a computer program, and a database. The internal memory provides an environment for operation of the operating system and the computer program in the non-volatile storage medium. The database of the computer device is used to store scene rendering data of large-scale digital twin models. The input/output interface of the computer device is used to exchange information between the processor and an external device. The communication interface of the computer device is used to communicate with an external terminal over a network connection. When the computer program is executed by the processor, a scene rendering method for a large-scale digital twin model is implemented.

In an exemplary embodiment, a computer device is provided, including a memory and a processor, where a computer program is stored in the memory, and the processor, when executing the computer program, is configured to implement the foregoing method.

In an exemplary embodiment, a computer-readable storage medium having a computer program is provided, and the computer program, when executed by a processor, implements the foregoing method.

In an exemplary embodiment, a computer program product is provided, which includes a computer program, and the computer program, when executed by a processor, implements the foregoing method.

A person skilled in the art can understand that all or part of the processes in the above embodiment methods may be implemented by instructing related hardware through a computer program. The computer program may be stored in a non-volatile computer-readable storage medium. When the computer program is executed, the computer program may include the procedures of the above method embodiments. Any reference to a memory, a database, or other medium used in the embodiments provided in the present disclosure may include at least one of a non-volatile memory and a volatile memory. The non-volatile memory may include a read-only memory (ROM), a magnetic tape, a floppy disk, a flash memory, an optical storage, a high-density embedded non-volatile memory, a resistive random access memory (ReRAM), a magnetoresistive random access memory (MRAM), a ferroelectric random access memory (FRAM), a phase change memory (PCM), a graphene memory, etc. The volatile memory may include a random access memory (RAM) or an external cache memory, etc. By way of illustration and not limitation, the RAM may be in various forms, such as a static random access memory (SRAM) or a dynamic random access memory (DRAM).

In the present disclosure, all actions to obtain signals, information, or data are carried out in compliance with the relevant data protection laws and policies of the country where they are located and with the authorization given by the owner of the corresponding device.

The database involved in each embodiment provided in the present disclosure may include at least one of a relational database and a non-relational database. The non-relational database may include, but is not limited to, a distributed database based on blockchain. The processor involved in each embodiment provided in the present disclosure may be a general-purpose processor, a central processing unit, a graphics processor, a digital signal processor, a programmable logic unit, a data processing logic unit based on quantum computing, etc., but is not limited thereto.

The technical features of the above embodiments may be combined arbitrarily. To make the description concise, all possible combinations of the technical features in the above embodiments are not described. However, these combinations should be considered to be within the scope of the description of the present disclosure as long as there is no contradiction in the combinations of these technical features.

In the text, the principle and embodiments of the present disclosure are described herein by using specific examples, the above descriptions of the embodiments are merely intended to help understand the methods and core idea of the present disclosure. In addition, for those of ordinary skill in the art, changes may be made to the specific embodiments and the scope of application according to the concept of the present disclosure. In summary, the content of the description should not be construed as a limitation to the present disclosure.

What is claimed is:

1. A scene rendering method for a digital twin model, comprising:
reconstructing, in an application phase, for any digital twin model, grid cells based on model information and texture information to determine grid cell data, wherein the digital twin model is a model with a closed boundary;
rendering, in a multi-threaded collaborative grid rendering phase, the model with the grid cells as an object, starting a corresponding thread group in a grid shader based on the grid cell data, and constructing a shared cache field in a graphics processing unit (GPU), wherein the thread group comprises a plurality of sub-threads, and each primitive in the grid cells corresponds to one or more sub-threads of the plurality of sub-threads; direct access between the plurality of sub-threads is enabled; the shared cache field is configured to store computational results of the plurality of sub-threads; and the computational results comprise grid rendering data, logical and dynamic data, and environmental data; and
performing, in a rasterization phase, rasterization processing on the computational results in the shared cache field to determine a rendered scene.

2. The scene rendering method according to claim 1, wherein the reconstructing, in the application phase, for any digital twin model, the grid cells based on the model information and the texture information to determine the grid cell data comprises:
calculating, for any digital twin model, based on the model information and the texture information, collapse costs of respective vertices in the digital twin model;
collapsing the digital twin model based on the collapse costs to determine a simplified digital twin model;
reconstructing the simplified digital twin model into the grid cells based on a model scale and a neighborhood selection in consideration of close proximity relations between vertices and patches, wherein each of the grid cells comprises a set of vertices and a plurality of primitives, and a shape of the patches is a triangle; and
reconstructing data information and data formats of the grid cells, and determining the grid cell data comprising a plurality of kinds of information, wherein the grid cell data comprises a grid description buffer, a vertex index buffer, a primitive index buffer, and grid attribute information; and the grid attribute information comprises a logic script, dynamic information, and grid culling for twin control.

3. The scene rendering method according to claim 2, further comprising: after the reconstructing the data information and the data formats of the grid cells, and determining the grid cell data comprising the plurality of kinds of information,
initializing, based on a vertex set and a triangle set in the grid cells, vertices in the vertex set, and calculating vertex degrees;
defining information parameters based on the vertex degrees, wherein the information parameters comprise a vertex cache, a maximum capacity of the vertex cache, a triangle output list, and a candidate triangle set; an initial value of the candidate triangle set is the triangle set; and the triangle output list is a vertex access order list;
selecting, from the candidate triangle set, a next triangle with a largest degree of overlap with a vertex in the vertex cache;
traversing each vertex in the next triangle, adding a vertex that is not in the vertex cache to the vertex cache, and updating the vertex access order list based on the maximum capacity of the vertex cache, until all triangles in the candidate triangle set are traversed, to determine a final vertex access order list; and
regenerating a vertex index order of triangles based on the final vertex access order list.

4. The scene rendering method according to claim 1, wherein the rendering, in the multi-threaded collaborative grid rendering phase, the model with the grid cells as the object, starting the corresponding thread group in the grid shader based on the grid cell data, and constructing the shared cache field in the GPU comprises:
processing the grid cell data by using a task shader in the multi-threaded collaborative grid rendering phase, to determine the logical and dynamic data and grid image data;
loading the grid image data in the grid shader, and reconstructing the grid image data into a plurality of pieces of grid cell data;
starting the corresponding thread group with the grid cell data as the object, and allocating the plurality of sub-threads to each primitive in the grid cell data, to determine the grid rendering data, wherein each of the plurality of sub-threads independently performs vertex transformation, attribute computing, triangle culling, and rendering tasks;
processing the logical and dynamic data by using a plurality of thread groups based on a compute shader, to determine the logical and dynamic data and the environmental data; and
constructing the shared cache field in the GPU, and storing the grid rendering data, the logical and dynamic data, and the environmental data into the shared cache field.

5. A scene rendering apparatus for a digital twin model, comprising:
a grid cell data determining module, configured to reconstruct, in an application phase, for any digital twin model, grid cells based on model information and texture information to determine grid cell data, wherein the digital twin model is a model with a closed boundary;
a grid rendering module, configured to render, in a multi-threaded collaborative grid rendering phase, the model with the grid cells as an object, start a corresponding thread group in a grid shader based on the grid cell data, and construct a shared cache field in a GPU, wherein the thread group comprises a plurality of sub-threads, and each primitive in the grid cells corresponds to one or more sub-threads of the plurality of sub-threads; direct access between the plurality of sub-threads is enabled; the shared cache field is configured to store computational results of the plurality of sub-threads; and the computational results comprise grid rendering data, logical and dynamic data, and environmental data; and
a rasterization processing module, configured to perform, in a rasterization phase, rasterization processing on the computational results in the shared cache field to determine a rendered scene.

6. A computer device, comprising:
a memory,
a processor, and
a computer program, stored in the memory and executable on the processor, wherein the processor executes the computer program to implement a scene rendering method;
wherein the scene rendering method comprises:
reconstructing, in an application phase, for any digital twin model, grid cells based on model information and texture information to determine grid cell data, wherein the digital twin model is a model with a closed boundary;
rendering, in a multi-threaded collaborative grid rendering phase, the model with the grid cells as an object, starting a corresponding thread group in a grid shader based on the grid cell data, and constructing a shared cache field in a GPU, wherein the thread group comprises a plurality of sub-threads, and each primitive in the grid cells corresponds to one or more sub-threads of the plurality of sub-threads; direct access between the plurality of sub-threads is enabled; the shared cache field is configured to store computational results of the plurality of sub-threads; and the computational results comprise grid rendering data, logical and dynamic data, and environmental data; and
performing, in a rasterization phase, rasterization processing on the computational results in the shared cache field to determine a rendered scene.

7. The computer device according to claim 6, wherein in the scene rendering method, the reconstructing, in the application phase, for any digital twin model, the grid cells based on the model information and the texture information to determine the grid cell data comprises:
calculating, for any digital twin model, based on the model information and the texture information, collapse costs of respective vertices in the digital twin model;
collapsing the digital twin model based on the collapse costs to determine a simplified digital twin model;
reconstructing the simplified digital twin model into the grid cells based on a model scale and a neighborhood selection in consideration of close proximity relations between vertices and patches, wherein each of the grid cells comprises a set of vertices and a plurality of primitives, and a shape of the patches is a triangle; and
reconstructing data information and data formats of the grid cells, and determining the grid cell data comprising a plurality of kinds of information, wherein the grid cell data comprises a grid description buffer, a vertex index buffer, a primitive index buffer, and grid attribute information; and the grid attribute information comprises a logic script, dynamic information, and grid culling for twin control.

8. The computer device according to claim 7, wherein the scene rendering method further comprises: after the reconstructing the data information and the data formats of the grid cells, and determining the grid cell data comprising the plurality of kinds of information,
initializing, based on a vertex set and a triangle set in the grid cells, vertices in the vertex set, and calculating vertex degrees;
defining information parameters based on the vertex degrees, wherein the information parameters comprise a vertex cache, a maximum capacity of the vertex cache, a triangle output list, and a candidate triangle set; an initial value of the candidate triangle set is the triangle set; and the triangle output list is a vertex access order list;
selecting, from the candidate triangle set, a next triangle with a largest degree of overlap with a vertex in the vertex cache;
traversing each vertex in the next triangle, adding a vertex that is not in the vertex cache to the vertex cache, and updating the vertex access order list based on the maximum capacity of the vertex cache, until all triangles in the candidate triangle set are traversed, to determine a final vertex access order list; and
regenerating a vertex index order of triangles based on the final vertex access order list.

9. The computer device according to claim 6, wherein in the scene rendering method, the rendering, in the multi-threaded collaborative grid rendering phase, the model with the grid cells as the object, starting the corresponding thread group in the grid shader based on the grid cell data, and constructing the shared cache field in the GPU comprises:
processing the grid cell data by using a task shader in the multi-threaded collaborative grid rendering phase, to determine the logical and dynamic data and grid image data;
loading the grid image data in the grid shader, and reconstructing the grid image data into a plurality of pieces of grid cell data;
starting the corresponding thread group with the grid cell data as the object, and allocating the plurality of sub-threads to each primitive in the grid cell data, to determine the grid rendering data, wherein each of the plurality of sub-threads independently performs vertex transformation, attribute computing, triangle culling, and rendering tasks;
processing the logical and dynamic data by using a plurality of thread groups based on a compute shader, to determine the logical and dynamic data and the environmental data; and
constructing the shared cache field in the GPU, and storing the grid rendering data, the logical and dynamic data, and the environmental data into the shared cache field.

10. A non-transitory computer-readable storage medium, having a computer program stored thereon, wherein the computer program, when executed by a processor, implements the scene rendering method according to claim 1.

11. The non-transitory computer-readable storage medium according to claim 10, wherein in the scene rendering method, the reconstructing, in the application phase, for any digital twin model, the grid cells based on the model information and the texture information to determine the grid cell data comprises:
calculating, for any digital twin model, based on the model information and the texture information, collapse costs of respective vertices in the digital twin model;
collapsing the digital twin model based on the collapse costs to determine a simplified digital twin model;
reconstructing the simplified digital twin model into the grid cells based on a model scale and a neighborhood selection in consideration of close proximity relations between vertices and patches, wherein each of the grid cells comprises a set of vertices and a plurality of primitives, and a shape of the patches is a triangle; and
reconstructing data information and data formats of the grid cells, and determining the grid cell data comprising a plurality of kinds of information, wherein the grid cell data comprises a grid description buffer, a vertex index buffer, a primitive index buffer, and grid attribute information; and the grid attribute information comprises a logic script, dynamic information, and grid culling for twin control.

12. The non-transitory computer-readable storage medium according to claim 11, wherein the scene rendering method further comprises: after the reconstructing the data information and the data formats of the grid cells, and determining the grid cell data comprising the plurality of kinds of information,
initializing, based on a vertex set and a triangle set in the grid cells, vertices in the vertex set, and calculating vertex degrees;
defining information parameters based on the vertex degrees, wherein the information parameters comprise a vertex cache, a maximum capacity of the vertex cache, a triangle output list, and a candidate triangle set; an initial value of the candidate triangle set is the triangle set; and the triangle output list is a vertex access order list;
selecting, from the candidate triangle set, a next triangle with a largest degree of overlap with a vertex in the vertex cache;
traversing each vertex in the next triangle, adding a vertex that is not in the vertex cache to the vertex cache, and updating the vertex access order list based on the maximum capacity of the vertex cache, until all triangles in the candidate triangle set are traversed, to determine a final vertex access order list; and
regenerating a vertex index order of triangles based on the final vertex access order list.

13. The non-transitory computer-readable storage medium according to claim 10, wherein in the scene rendering method, the rendering, in the multi-threaded collaborative grid rendering phase, the model with the grid cells as the object, starting the corresponding thread group in the grid shader based on the grid cell data, and constructing the shared cache field in the GPU comprises:
processing the grid cell data by using a task shader in the multi-threaded collaborative grid rendering phase, to determine the logical and dynamic data and grid image data;
loading the grid image data in the grid shader, and reconstructing the grid image data into a plurality of pieces of grid cell data;
starting the corresponding thread group with the grid cell data as the object, and allocating the plurality of sub-threads to each primitive in the grid cell data, to determine the grid rendering data, wherein each of the plurality of sub-threads independently performs vertex transformation, attribute computing, triangle culling, and rendering tasks;
processing the logical and dynamic data by using a plurality of thread groups based on a compute shader, to determine the logical and dynamic data and the environmental data; and
constructing the shared cache field in the GPU, and storing the grid rendering data, the logical and dynamic data, and the environmental data into the shared cache field.
